(19) United States
(12) Patent Application Publication
(10) Pub. No.: US 2009/0038680 A1
(43) Pub. Date: Feb. 12, 2009

(54) SOLAR BUILDING

(75) Inventor: GA-LANE CHEN, Santa Clara, CA (US)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 12/039,034

(22) Filed: Feb. 28, 2008

(30) Foreign Application Priority Data
Aug. 9, 2007 (CN) 200710201307.8

(51) Int. Cl. H01L 31/00

(52) U.S. Cl. 136/256

(57) ABSTRACT

An exemplary solar building includes a roof and a peripheral side wall enclosure supporting the roof. The roof and the peripheral sidewall enclosure are comprised of glass. A solar cell is formed on an exterior surface of the roof and the peripheral side wall enclosure. The solar cell includes a substrate, a back metal contact layer formed on the substrate, a P-type semiconductor layer formed on the back metal contact layer, a P-N junction layer formed on the P-type semiconductor layer, an N-type semiconductor layer formed on the P-N junction layer, and a front metal contact layer formed on the N-type semiconductor layer.

### CROSS-REFERENCE TO RELATED APPLICATIONS

This application is related to the following commonly-assigned copending applications: Ser. No. 11/967,008, entitled “SOLAR CELL WITH FLEXIBLE SUBSTRATE” (attorney docket number US 14906); Ser. No. 11/967,009, entitled “SOLAR CELL WITH FLEXIBLE SUBSTRATE” (attorney docket number US 14910); and Ser. No. 11/933,941, entitled “FLEXIBLE SOLAR CELL” (attorney docket number US 15052). Disclosures of the above-identified applications are incorporated herein by reference.

### BACKGROUND

1. Technical Field

The present invention relates to a building with an energy collecting device and, particularly, to a building with solar cells formed thereon.

2. Description of Related Art

A solar cell is a device that converts solar energy into electrical energy. The solar cell is a clean energy power supply source. Nowadays, solar cells are widely used in buildings, and such buildings are called solar buildings.

Generally, solar cells are disposed on a roof of the solar building. Generally, an area of the roof mainly determines an area of the solar cells for absorbing solar energy. Thus, the area of the roof limits the area of the solar cells for receiving sun rays. The solar cells can only receive the sun rays illuminating the roof. Accordingly, only a small part of solar energy is used.

Therefore, a new solar building is desired to overcome the above described shortcomings.

### SUMMARY

An exemplary solar building includes a roof and a peripheral side wall enclosure supporting the roof. The roof and the peripheral sidewall enclosure are comprised of glass. A solar cell is formed on an exterior surface of the roof and the peripheral side wall enclosure. The solar cell includes a substrate, a back metal contact layer formed on the substrate, a P-type semiconductor layer formed on the back metal contact layer, a P-N junction layer formed on the P-type semiconductor layer, an N-type semiconductor layer formed on the P-N junction layer, and a front metal contact layer formed on the N-type semiconductor layer.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic, isometric view of a solar building according to a first embodiment;

FIG. 2 is a schematic, isometric exploded view of the solar building of FIG. 1;

FIG. 3 is a schematic, cross-sectional view of the solar building of FIG. 1 taken along the line III-III thereof; and

FIG. 4 is a schematic, perspective view of a solar building according to a second embodiment.

### DETAILED DESCRIPTION OF THE EMBODIMENTS

Embodiments will now be described in detail below with reference to the drawings.

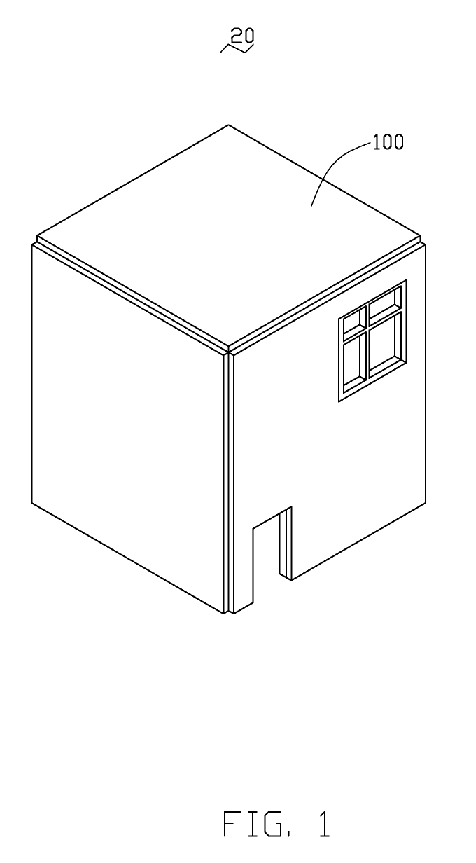

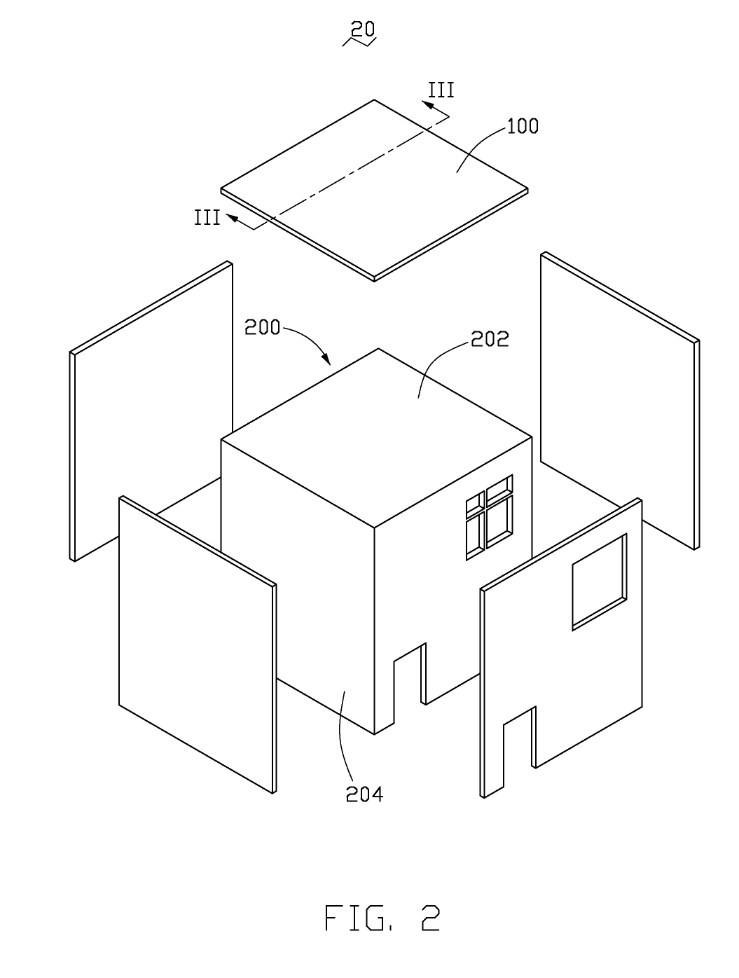

Referring to FIGS. 1 and 2, a solar building 20 of a first embodiment is shown. The solar building 20 includes a main body 200 and a plurality of solar cells formed on the main body 200.

The main body 200 can be a cuboid or a cylinder. In the present embodiment, the main body 200 is a cuboid. The main body 200 includes a roof 202 and a peripheral side wall enclosure (i.e., four side walls) 204 supporting the roof 202. The main body 200 can be made of reinforced concrete, glass, or fiber glass.

Solar cells 100 are disposed on an upper surface of the roof 202 and exterior surfaces of the four side walls 204. The solar cells 100 can be attached to or fixed on the roof 202 and the side walls 204. The solar cells 100 are configured for receiving sun rays and converting energy from the sun rays into electric energy. The solar cells 100 can be electrically connected with a converter (not shown), and the converter can be electrically connected with electrical equipment (not shown; e.g., an illumination equipment). In this way, the solar cells 100 provide electricity so as to power the electrical equipment.

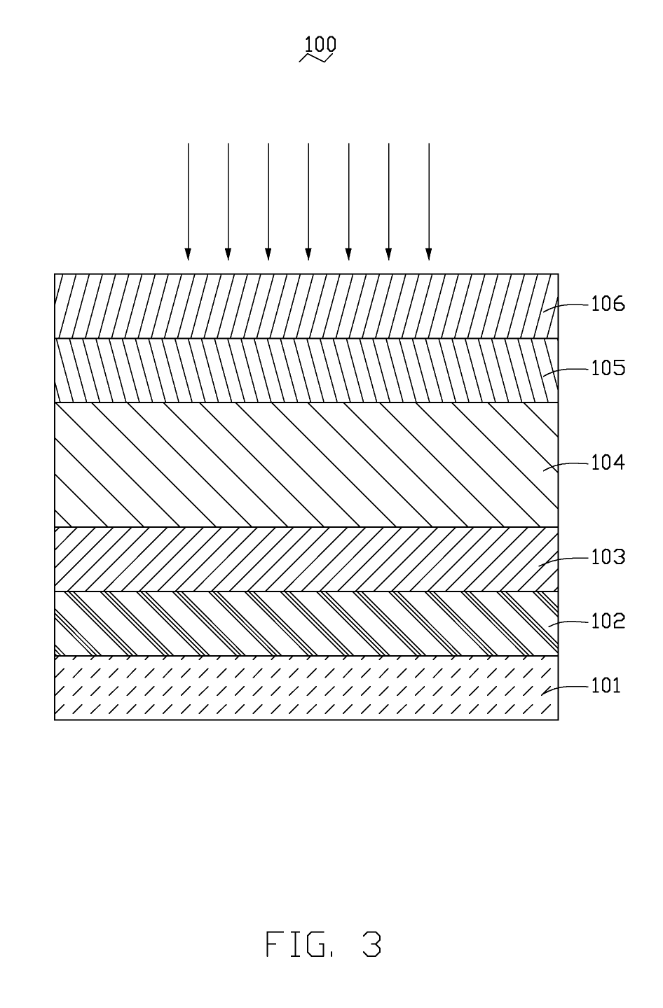

Referring to FIG. 3, the solar cell 100 includes a substrate 101. A back metal contact layer 102, a P-type semiconductor layer 103, a P-N junction layer 104, an N-type semiconductor layer 105, and a front metal contact layer 106 are formed on the substrate 101 in the order written.

The substrate 101 can be rigid or flexible. The rigid substrate 101 can be made of glass. The flexible substrate 101 can be made of stainless steel, aluminum magnesium alloy, or polymer. When the substrate 101 is flexible, the solar cell 100 can be bent to conform different geometric surfaces, thus making the design more convenient and flexible.

The back metal contact layer 102 can be made of silver, copper, molybdenum, aluminum, copper aluminum alloy, silver copper alloy, or copper molybdenum alloy. The back metal contact layer 102 can be formed on the substrate 101 by sputtering or deposition.

The P-type semiconductor layer 103 can be made of P-type amorphous silicon (P-a-Si), particularly, P-type amorphous silicon with hydrogen (P-a-Si:H). Also, the P-type semiconductor layer 103 can be made of III-V group compound semiconductors or II-VI group compound semiconductors, particularly above semiconductors doped with aluminum, gallium, or indium, e.g., aluminum gallium nitride (AlGaN), aluminum gallium arsenide (AlGaAs).

The P-N junction layer 104 can be made of III-V or I-III-VI group compound semiconductors, e.g., cadmium telluride (CdTe), copper indium diselenide (CuInSe₂, CIS). Also, The P-N junction layer 104 can be made of copper indium gallium diselenide (CuIn₁₋ₓGaSe₂, CIGS). The P-N junction layer 104 can be formed on the P-type semiconductor layer using chemical vapor deposition or sputtering.

The N-type semiconductor layer 105 can be made of N-type amorphous silicon (N-a-Si), particularly, N-type amorphous silicon with hydrogen (N-a-Si:H). Also, the N-type semiconductor layer 105 can be made of III-V group compound semiconductors or II-VI group compound semiconductors, particularly above semiconductors doped with nitrogen, phosphorus, arsenic, e.g., gallium nitride (GaN), indium gallium phosphide (InGaP).

The front metal contact layer 106 can be made of transparent conductive oxide, e.g., indium tin oxide (ITO) or zinc oxide.

In order to add/improve waterproof ability of the solar cell 100, a protective layer (not shown) can be formed on the front metal contact layer 106. The protective layer can be made of resin.

In the present embodiment, the solar building 20 has solar cells 100 formed on the upper surface of the roof 202 and the outer surfaces of the four side walls 204. Accordingly, the solar building 20 has a large area covered with solar cells 100. Therefore, efficiency of the solar building 20 in collecting the suns rays is improved.

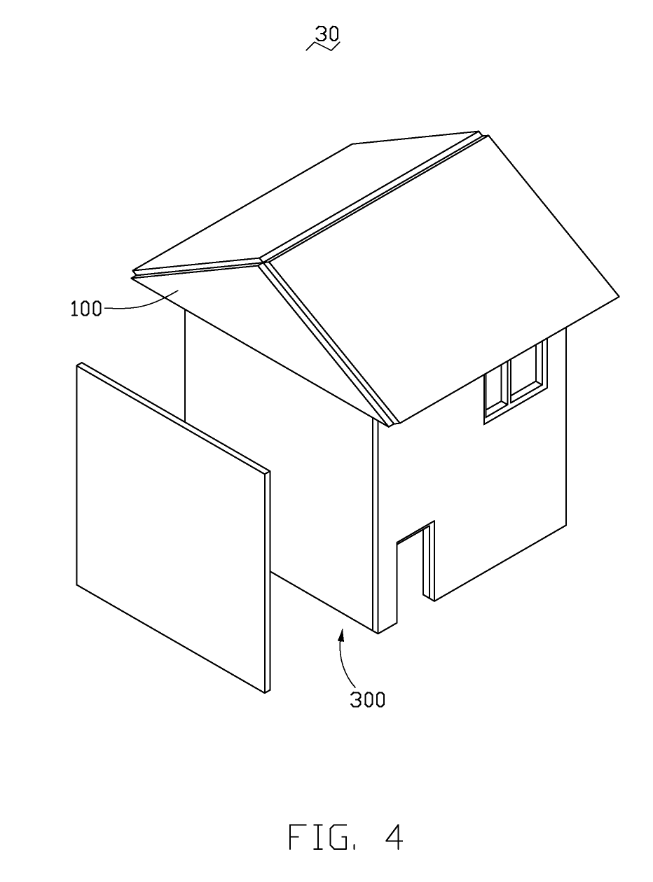

Referring to FIG. 4, a solar building 30 according to a second embodiment is shown. The solar building 30 is similar to the solar building 20, but the roof (not labeled) of the main body 300 is triangular in cross section. The roof has solar cells 100 positioned on side surfaces thereof.

While certain embodiments have been described and exemplified above, various other embodiments will be apparent to those skilled in the art from the foregoing disclosure. The present invention is not limited to the particular embodiments described and exemplified but is capable of considerable variation and modification without departure from the scope of the appended claims.

What is claimed is:

1. A solar building comprising:
a roof;
a peripheral side wall enclosure supporting the roof, the roof and the peripheral sidewall enclosure being comprised of glass; and
a solar cell formed on an exterior surface of the roof and the peripheral side wall enclosure, the solar cell comprising a substrate, a back metal contact layer formed on the substrate, a P-type semiconductor layer formed on the back metal contact layer, a P-N junction layer formed on the P-type semiconductor layer, an N-type semiconductor layer formed on the P-N junction layer, and a front metal contact layer formed on the N-type semiconductor layer.

2. The solar building as claimed in claim 1, wherein the peripheral side wall enclosure is four-sided.

3. The solar building as claimed in claim 1, wherein the substrate is made of glass, stainless steel, aluminum, magnesium alloy, or polymer.

4. The solar building as claimed in claim 1, wherein the P-type semiconductor layer is comprised of P-type amorphous silicon, aluminum gallium nitride, or aluminum gallium arsenide.

5. The solar building as claimed in claim 1, wherein the P-N junction layer is comprised of cadmium telluride, copper indium diselenide, or copper indium gallium diselenide.

6. The solar building as claimed in claim 1, wherein the N-type semiconductor layer is comprised of N-type amorphous silicon, gallium nitride, or indium gallium phosphide.

7. The solar building as claimed in claim 1, wherein the front metal contact layer is comprised of transparent conductive oxide.

8. The solar building as claimed in claim 1, wherein the transparent conductive oxide is selected from the group consisting of indium tin oxide and zinc oxide.

9. A glass building comprising:
a roof;
a peripheral side wall enclosure supporting the roof, the peripheral sidewall enclosure being comprised of glass; and
a solar cell formed on an exterior surface of the roof and the peripheral side wall enclosure, the solar cell comprising a substrate, a back metal contact layer formed on the substrate, a P-type semiconductor layer formed on the back metal contact layer, a P-N junction layer formed on the P-type semiconductor layer, an N-type semiconductor layer formed on the P-N junction layer, and a front metal contact layer formed on the N-type semiconductor layer.

10. The solar building as claimed in claim 9, wherein the peripheral side wall enclosure is four-sided.

11. The solar building as claimed in claim 9, wherein the substrate is made of glass, stainless steel, aluminum, magnesium alloy, or polymer.

12. The solar building as claimed in claim 9, wherein the P-type semiconductor layer is comprised of P-type amorphous silicon, aluminum gallium nitride, or aluminum gallium arsenide.

13. The solar building as claimed in claim 9, wherein the P-N junction layer is comprised of cadmium telluride, copper indium diselenide, or copper indium gallium diselenide.

14. The solar building as claimed in claim 9, wherein the N-type semiconductor layer is comprised of N-type amorphous silicon, gallium nitride, or indium gallium phosphide.

15. The solar building as claimed in claim 9, wherein the front metal contact layer is comprised of transparent conductive oxide.

16. The solar building as claimed in claim 9, wherein the transparent conductive oxide is selected from the group consisting of indium tin oxide and zinc oxide.
